(19) United States
(12) Patent Application Publication
(10) Pub. No.: US 2026/0155650 A1
(43) Pub. Date: Jun. 4, 2026

(54) Control method for energy storage converter

(71) Applicant: NORTH CHINA ELECTRIC POWER UNIVERSITY, Beijing (CN)

(72) Inventors: Tong WANG, Beijing (CN); Qian XU, Beijing (CN); Zengping WANG, Beijing (CN)

(73) Assignee: NORTH CHINA ELECTRIC POWER UNIVERSITY, Beijing, BJ (CN)

(21) Appl. No.: 19/457,098

(22) Filed: Jan. 22, 2026

Related U.S. Application Data
(63) Continuation of application No. PCT/CN2025/135993, filed on Nov. 19, 2025.

(30) Foreign Application Priority Data
May 15, 2025 (CN) 202510625216.5

(51) Int. Cl. H02J 3/0012; G01R 31/42; H02J 3/01; H02J 3/32; H02J 3/38; H02J 101/20

(52) U.S. Cl. CPC H02J 3/0012; G01R 31/42; H02J 3/01; H02J 3/32; H02J 3/38; H02J 2101/20

(57) ABSTRACT

The present disclosure relates to a control method for an energy storage converter. The method includes: determining a current fault component; determining a voltage fault component; determining a fault component of a positive-sequence current of the energy storage converter in a dq coordinate system of the new energy converter; determining a fault component of a current in a dq coordinate system of the energy storage converter; determining dq-axis currents of the energy storage converter according to the fault component of the current in the dq coordinate system of the energy storage converter and a pre-fault current of the energy storage converter; and controlling the energy storage converter to output current according to the dq-axis currents of the energy storage converter, so as to reduce an impact of the fault.

### CROSS-REFERENCE TO RELATED APPLICATION

This application is a Section 371 National Stage Application of International Application No. PCT/CN2025/135993, filed on Nov. 19, 2025, entitled “Control method for energy storage converter”, which claims priority to Chinese Application No. 202510625216.5, filed on May 15, 2025, incorporated herein by reference in their entirety.

### TECHNICAL FIELD

The present disclosure relates to the field of power engineering, and in particular to a control method for an energy storage converter.

### BACKGROUND

At present, the development of new energy sources is booming, and converters are installed in various new energy power plants. In case where a new energy power plant is connected to a power system, there is currently no suitable method to determine the faulted phase and thus take remedial measures when a phase fault occurs. Since a new energy power plant differs from a conventional generator in both structural configuration and operating principle, the direct application of fault phase selection formula designed for generators leads to inaccurate fault phase identification in the new energy power plant. As a result, effective remedial measures cannot be properly performed, thereby failing to reduce the adverse impact of the fault and to restore the stability of the power system.

### SUMMARY

In view of the problems existing in the prior art, the present disclosure provides a control method for an energy storage converter. To achieve the above objective, the technical solutions adopted by the present disclosure are as follows:

A control method for an energy storage converter, comprising:
determining a voltage at a point of common coupling of the energy storage converter and a new energy converter;
determining, based on a pre-stored functional relationship between the voltage at the point of common coupling and an output current of the new energy converter, and the voltage at the point of common coupling, an output current of the new energy converter after a fault occurs;
determining a current fault component according to the output current of the new energy converter and a rated operating current of the new energy converter;
determining a voltage fault component according to the voltage at the point of common coupling and a rated operating voltage of the new energy converter;
determining a fault component of a positive-sequence current of the energy storage converter in a dq coordinate system of the new energy converter according to the current fault component and the voltage fault component;
determining a fault component of a current in a dq coordinate system of the energy storage converter according to the fault component of the current in the dq coordinate system of the new energy converter and a transformation coefficient;
determining dq-axis currents of the energy storage converter according to the fault component of the current in the dq coordinate system of the energy storage converter and a rated current of the energy storage converter; and
controlling the energy storage converter to output current according to the dq-axis currents of the energy storage converter, so as to reduce an impact of the fault.

According to some embodiments of the present disclosure, in response to a duration of the fault being greater than a predetermined time threshold, the energy storage converter outputs dq-axis currents according to a prescribed standard.

According to some embodiments of the present disclosure, in response to a duration of the fault being less than a predetermined time threshold, the method returns to the step of “determining, based on a pre-stored functional relationship between the voltage at the point of common coupling and an output current of the new energy converter, and the voltage at the point of common coupling, an output current of the new energy converter after a fault occurs”.

According to some embodiments of the present disclosure, the step of “determining a fault component of a positive-sequence current of the energy storage converter in a dq coordinate system of the new energy converter according to the current fault component and the voltage fault component” comprises: determining a magnitude and an angle of the fault component of the positive-sequence current of the energy storage converter in the dq coordinate system;
the step of “determining a magnitude of the fault component of the positive-sequence current of the energy storage converter in the dq coordinate system” comprises:
determining an angle of the voltage fault component and an angle of the current fault component;
determining a difference between the angle of the voltage fault component and the angle of the current fault component;
determining a sine value according to the difference, a predetermined ideal angle, and a first constant; and
calculating a product of the current fault component and the sine value to obtain the magnitude of the fault component of the positive-sequence current of the energy storage converter in the dq coordinate system.

According to some embodiments of the present disclosure, the step of “determining a an angle of the fault component of the positive-sequence current of the energy storage converter in the dq coordinate system” comprises:
determining the angle of the fault component of the positive-sequence current of the energy storage converter in the dq coordinate system according to the angle of the voltage fault component, the predetermined ideal angle, and a second constant.

According to some embodiments of the present disclosure, the step of “determining a fault component of a positive-sequence current of the energy storage converter in a dq coordinate system of the new energy converter according to the current fault component and the voltage fault component” comprises:

calculating the fault component of the positive-sequence current of the energy storage converter in the dq coordinate system according to the following equations:

$$\{ \begin{matrix}\vert Δ {\dot{I}}_{ESS 1}^{′} \vert = \vert Δ {\dot{I}}_{RES 1} \vert sin [ arg ( Δ {\dot{U}}_{PCC 1} ) - arg ( Δ {\dot{I}}_{RES 1} ) - {θ}_{Plant 1} + π ] \\ arg ( Δ {\dot{I}}_{ESS 1}^{′} ) = arg ( Δ {\dot{U}}_{PCC 1} ) - {θ}_{Plant 1} + π / 2\end{matrix} ;$$

where, Δİ_{RES1} is the current fault component;
Δİ_{ESS1}′ is the fault component of the positive-sequence current of the energy storage converter in the dq coordinate system;
Δ\dot{U}_{PCC1} is the voltage fault component;
θ_{Plant1} is the predetermined ideal angle.

According to some embodiments of the present disclosure, the step of “determining dq-axis currents of the energy storage converter according to the fault component of the current in the dq coordinate system of the energy storage converter and a rated current of the energy storage converter” comprises:

$$\{ \begin{matrix}{i}_{d 1} = \vert Δ {\dot{I}}_{ESS 1 [ 0 ]} \vert sin {φ}_{pcc} + \vert Δ {\dot{I}}_{ESS 1} \vert sin [ arg ( Δ {\dot{I}}_{ESS 1} ) ] \\ {i}_{q 1} = \vert Δ {\dot{I}}_{ESS 1 [ 0 ]} \vert cos {φ}_{pcc} + \vert Δ {\dot{I}}_{ESS 1} \vert cos [ arg ( Δ {\dot{I}}_{ESS 1} ) ]\end{matrix} ;$$

where, Δİ_{ESS1[0]} is the rated current of the energy storage converter;
φ_{pcc} is a voltage deviation angle before and after the fault;
i_{d1} is a d-axis current of the energy storage converter;
i_{q1} is a q-axis current of the energy storage converter; and
Δİ_{ESS1} is the fault component of the current of the energy storage converter in the dq coordinate system.

According to some embodiments of the present disclosure, the voltage at the point of common coupling of the energy storage converter is identical to the voltage at the point of common coupling of the new energy converter.

According to some embodiments of the present disclosure, the functional relationship between the voltage at the point of common coupling and the output current of the new energy converter is expressed as:

$$\{ \begin{matrix}{\dot{I}}_{RES 1} = {f}_{RES 1} ( {\dot{U}}_{PCC 1} ) \\ {\dot{I}}_{RES 2} = {f}_{RES 2} ( {\dot{U}}_{PCC 2} )\end{matrix} ;$$

where, İ_{RES1} is the positive-sequence current output by the new energy converter;
İ_{RES2} is a negative-sequence current output by the new energy converter;
\dot{U}_{PCC1} is a positive-sequence voltage at the point of common coupling;
\dot{U}_{PCC2} is a negative-sequence voltage at the point of common coupling;
f_{RES1} is a first function; and
f_{RES2} is a second function.

According to some embodiments of the present disclosure, before determining the voltage at the point of common coupling of the energy storage converter and the new energy converter, the method further comprises: determining that a fault occurs; and
after determining the voltage at the point of common coupling of the energy storage converter and the new energy converter, the method further comprises: controlling the energy storage converter, in response to the voltage at the point of common coupling dropping to a predetermined threshold, to enter a low-voltage ride-through stage.

Compared with the prior art, the present disclosure has the following beneficial effects:

According to the technical solutions of the present disclosure, when a fault occurs, the energy storage converter is capable of outputting current based on calculated dq-axis currents, thereby reducing the impact of the fault. By estimating an output current of the new energy converter, the energy storage converter adjusts its own output current such that the overall output current of the new energy power plant satisfies requirements of conventional fault phase selection methods. Furthermore, after the fault lasts for a predetermined period of time, the control strategy is switched to a control strategy capable of achieving continuous and smooth active power regulation and stabilizing the voltage at the point of common coupling according to the voltage control objective, thereby ensuring improved performance of fault phase selection method for the new energy power plant.

### BRIEF DESCRIPTION OF THE DRAWINGS

The accompanying drawings, which are incorporated into and constitute a part of the specification, illustrate embodiments consistent with the present disclosure and, together with the specification, serve to explain the principles of the present disclosure.

FIG. 1 is a flowchart illustrating a control method for an energy storage converter according to an exemplary embodiment;

FIG. 2 is a control topology diagram of an energy storage converter according to an exemplary embodiment;

FIG. 3 illustrates a dq coordinate system of a new energy converter according to an exemplary embodiment;

FIG. 4 illustrates current waveforms of an energy storage converter, a new energy converter, and a new energy power plant according to an exemplary embodiment;

FIG. 5A illustrates an equivalent impedance angle of a new energy power plant under an AG fault when a control strategy of the present application is adopted according to an exemplary embodiment;

FIG. 5B illustrates an equivalent impedance angle of a new energy power plant under an AG fault when a control strategy of the present application is adopted according to an exemplary embodiment;

FIG. 6A illustrates a relationship of current sequence components on a new energy side under an AG fault when a control strategy of the present application is adopted according to an exemplary embodiment;

FIG. 6B illustrates a relationship of current sequence components on a new energy side under an AG fault when a conventional control strategy is adopted according to an exemplary embodiment;

FIG. 7A illustrates a relationship of current sequence components on a new energy side when the fault type is changed to a BC fault and a control strategy of the present application is adopted according to an exemplary embodiment;

FIG. 7B illustrates a relationship of current sequence components on a new energy side when the fault type is changed to a BC fault and a conventional control strategy is adopted according to an exemplary embodiment;

FIG. 8A illustrates a relationship of current sequence components on a new energy side under a BCG fault when a control strategy of the present application is adopted according to an exemplary embodiment;

FIG. 8B illustrates a relationship of current sequence components on a new energy side under a BCG fault when a conventional control strategy is adopted according to an exemplary embodiment;

FIG. 9A illustrates a relationship of current sequence components on a new energy side under a resistive condition according to an exemplary embodiment; and

FIG. 9B illustrates another relationship of current sequence components on a new energy side under a resistive condition according to an exemplary embodiment.

### DETAILED DESCRIPTION OF EMBODIMENTS

The present disclosure is further described below with reference to the accompanying drawings. The following embodiments are only used to more clearly illustrate the technical solutions of the present disclosure, and are not intended to limit the scope of protection of the present disclosure. It should be noted that the following detailed descriptions are exemplary and are intended to provide further explanation of the present application.

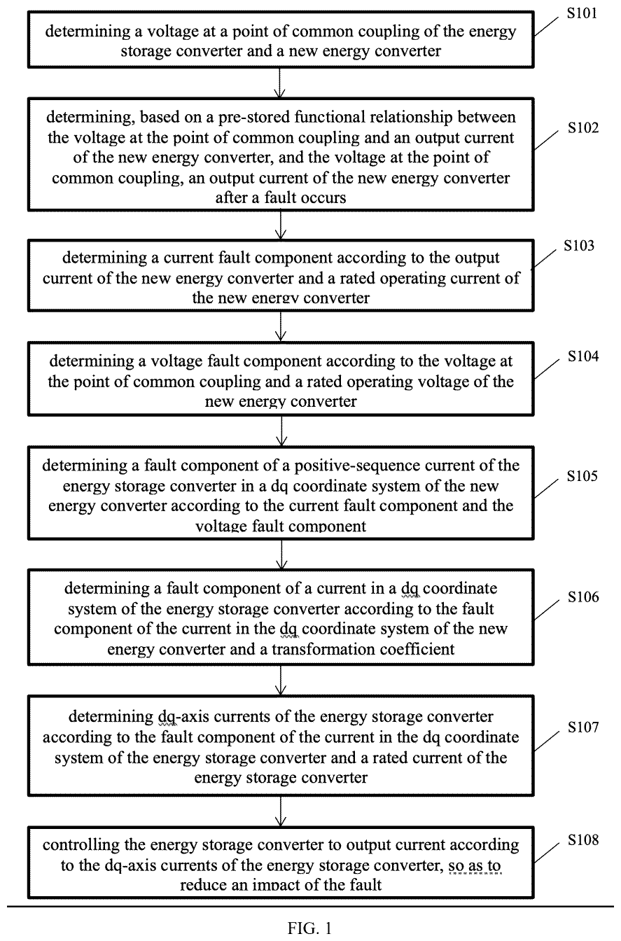

Based on this, the present application proposes a control method for an energy storage converter. Referring to FIG. 1, the method includes:

In Step S101, determine a voltage at a point of common coupling of the energy storage converter and a new energy converter.

In some embodiments, the voltage at the point of common coupling of the energy storage converter is the same as the voltage at the point of common coupling of the new energy converter.

In some embodiments, before determining the voltage at the point of common coupling of the energy storage converter and the new energy converter, the method further includes determining that a fault occurs.

In some embodiments, after determining the voltage at the point of common coupling of the energy storage converter and the new energy converter, the method further includes: controlling the energy storage converter, in response to the voltage at the point of common coupling dropping to a predetermined threshold, to enter a low-voltage ride-through stage.

In this embodiment, when a fault occurs, the energy storage converter detects that the voltage at the point of common coupling drops below 0.9 p.u., and enters the low-voltage ride-through stage.

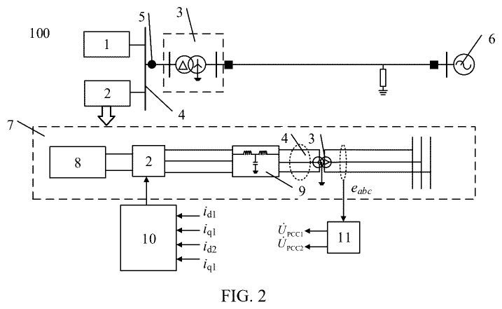

As shown in FIG. 2, a new energy power plant 100 mainly includes a new energy converter 1 and an energy storage converter 2. Electric energy from the two converters is jointly fed into a collector line 4 of the new energy power plant 100, and is stepped up by a transformer 3 to be connected to a power grid 6. Reference numeral 5 denotes a common connection point of the two converters, that is, the point of common coupling. Since the new energy converter 1 and the energy storage converter 2 are equivalently connected to the collector line 4, the two converters share the same point of common coupling 5, that is, the point-of-common-coupling voltage of the two converters is identical. A dashed box 7 illustrates a power electronic circuit topology of the energy storage converter 2. A DC voltage source 8 provides DC electric energy to the energy storage converter 2, for example, supplied by an energy storage unit such as a lithium battery pack. When the energy storage converter 2 is discharging, DC electric energy is inverted into AC electric energy. A filter 9 filters harmonics of an output current, such that the grid-connected current approaches a sinusoidal waveform and satisfies grid power quality requirements. The filtered AC electric energy is fed into the collector line 4, and after being stepped up by the transformer 3, is connected to the power grid, thereby completing grid connection of electric energy. In a core control loop of the energy storage converter 2, a positive- and negative-sequence separation phase-locked loop 11 acquires a point-of-common-coupling voltage e_{abc}. Through a positive- and negative-sequence separation algorithm and phase-locked loop technology, a positive-sequence PCC voltage \dot{U}_{PCC1} and a negative-sequence PCC voltage \dot{U}_{PCC2} are extracted, and are converted into per-unit values. When the energy storage converter 2 detects that a magnitude of the positive-sequence PCC voltage is less than 0.9 p.u., the energy storage converter 2 and the new energy converter 1 synchronously enter the low-voltage ride-through stage, and the energy storage converter 2 records this time as t_{f}. Meanwhile, in order to achieve precise control, it is necessary to determine positive- and negative-sequence current components of the energy storage converter 2 in a dq coordinate system, namely i_{d1}, i_{q1}, i_{d2}, i_{q2}, and to input these current components into a control structure 10 to provide references for current closed-loop control.

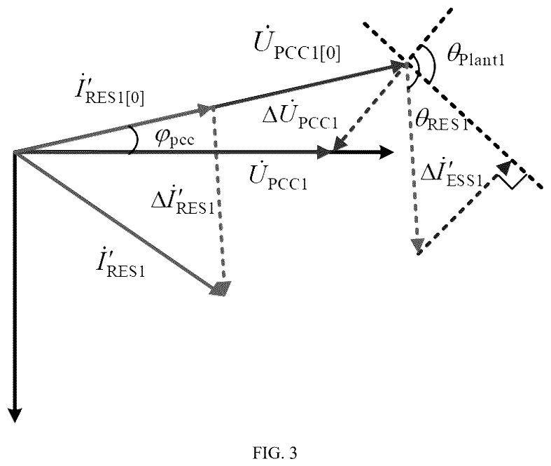

A phasor analysis of the new energy converter in the dq coordinate system is shown in FIG. 3. \dot{U}_{PCC1} denotes the voltage at the point of common coupling. By substituting \dot{U}_{PCC1} into a functional relationship between the voltage at the point of common coupling and an output current of the new energy converter, an output current İ_{RES1}′ of the new energy converter after the fault occurs is determined. İ_{RES1[0]} denotes an output current of the new energy converter before the fault occurs. A current fault component of the new energy converter Δİ_{RES1}′ is determined using İ_{RES1}′−İ_{RES1[0]}′.

\dot{U}_{PCC1[0]} denotes a voltage of the new energy converter before the fault occurs, that is, the voltage at the point of common coupling before the fault occurs, which may be represented by a rated operating voltage. A voltage fault component Δ\dot{U}_{PCC1} is determined using \dot{U}_{PCC1}−\dot{U}_{PCC1[0]}. φ_{pcc} denotes a voltage deviation angle before and after the fault, and θ_{RES1} denotes a deviation angle between the current fault component and the voltage fault component +π. Based on Δİ_{RES1}′ and \dot{U}_{PCC1}, a fault component of a positive-sequence current of the energy storage converter in the dq coordinate system, denoted as Δİ_{ESS1}′, is determined. θ_{Plant1} is a predetermined ideal angle. In the present application, by determining the fault component Δİ_{RES1}′ of the positive-sequence current of the energy storage converter in the dq coordinate system and calculating dq-axis currents of the energy storage converter, the energy storage converter is controlled to output dq-axis currents, so as to compensate for a current deviation caused by the fault in the new energy converter. As a result, an overall fault phase of the new energy power plant is returned to the predetermined ideal angle θ_{Plant1}, thereby satisfying requirements of conventional fault phase selection methods.

In Step S102, determining, based on a pre-stored functional relationship between the voltage at the point of common coupling and an output current of the new energy converter, and the voltage at the point of common coupling, an output current of the new energy converter after a fault occurs.

In this embodiment, the functional relationship between the voltage at the point of common coupling and the output current of the new energy converter is as follows:

$$\{ \begin{matrix}{\dot{I}}_{RES 1} = {f}_{RES 1} ( {\dot{U}}_{PCC 1} ) \\ {\dot{I}}_{RES 2} = {f}_{RES 2} ( {\dot{U}}_{PCC 2} )\end{matrix}$$

where, İ_{RES1} is the positive-sequence current output by the new energy converter;
İ_{RES2} is a negative-sequence current output by the new energy converter;
\dot{U}_{PCC1} is a positive-sequence voltage at the point of common coupling;
\dot{U}_{PCC2} is a negative-sequence voltage at the point of common coupling;
f_{RES1} is a first function; and
f_{RES2} is a second function.

f_{RES1} and f_{RES2} are configured according to technical requirements for grid connection of onshore wind farms and photovoltaic power stations, covering key technical conditions such as active power control, reactive power capacity configuration, voltage and frequency adaptability, fault ride-through, inertia response and primary frequency regulation, power forecasting, power quality monitoring, secondary system security, and grid-connection testing and evaluation, so as to ensure safe and stable operation of a power system after grid connection of a new energy power plant.

Since the energy storage converter and the new energy converter are connected to a line at the same point, the voltage level at the point of common coupling is the same for both, and is \dot{U}_{PCC1} and \dot{U}_{PCC2}. Therefore, the energy storage converter can determine the output current of the new energy converter after the fault occurs according to the above formulas (which may be stored in advance in the energy storage converter as known functions) and its own point-of-common-coupling voltage. The positive- and negative-sequence output currents of the new energy converter estimated by the energy storage converter are denoted as \dot{U}_{PCC2} and İ_{RES2}.

In Step S103, determine a current fault component according to the output current of the new energy converter and a rated operating current of the new energy converter.

It should be noted that, in this embodiment, the rated operating current of the new energy converter refers to an output current of the new energy converter before the fault occurs, that is, an output current during normal operation of the new energy converter, which is referred to as the rated operating current in this embodiment.

In Step S104, determine a voltage fault component according to the voltage at the point of common coupling and a rated operating voltage of the new energy converter.

It should be noted that, in this embodiment, the rated operating voltage of the new energy converter refers to an output voltage of the new energy converter before the fault occurs. Since the point-of-common-coupling voltage (the voltage at the point of common coupling) of the new energy converter and the energy storage converter is the same, the output voltage of the new energy converter before the fault also corresponds to the point-of-common-coupling voltage before the fault, which is referred to as the rated operating voltage in this embodiment.

In this embodiment, an output current of the new energy converter during normal operation is İ_{RES1[0]}′, which is known to the converter (and may be stored in advance in the energy storage converter as a known function). Therefore, fault components of the voltage at the point of common coupling and the estimated output current of the new energy converter can be obtained respectively, that is, post-fault data minus pre-fault data:

$$\{ \begin{matrix}{\dot{Δ U}}_{PCC 1} = {\dot{U}}_{PCC 1} - {\dot{U}}_{PCC 1 [ 0 ]} \\ Δ {\dot{I}}_{RES 1}^{′} = {\dot{I}}_{RES 1}^{′} - {\dot{I}}_{RES 1 [ 0 ]}^{′}\end{matrix}$$

In Step S105, determine a fault component of a positive-sequence current of the energy storage converter in a dq coordinate system of the new energy converter according to the current fault component and the voltage fault component.

In Step S106, determine a fault component of a current in a dq coordinate system of the energy storage converter according to the fault component of the current in the dq coordinate system of the new energy converter and a transformation coefficient.

It should be noted that, in this embodiment, the fault component of the current in the dq coordinate system of the new energy converter refers to the fault component of the positive-sequence current of the energy storage converter in the dq coordinate system (that is, the dq coordinate system of the new energy converter) determined in Step S105. That is, in this embodiment, according to the fault component of the positive-sequence current of the energy storage converter in the dq coordinate system of the new energy converter and the transformation coefficient, the fault component of the positive-sequence current of the energy storage converter in the dq coordinate system of the new energy converter is transformed into the fault component of the positive-sequence current of the energy storage converter in the dq coordinate system of the energy storage converter.

In this embodiment, since rated current values of the new energy converter and the energy storage converter are different, by transforming from the dq coordinate system of the new energy converter to the dq coordinate system of the energy storage converter, the following calculation formula can be obtained:

$$\{ \begin{matrix}\vert Δ {\dot{I}}_{ESS 1} \vert = β \vert Δ {\dot{I}}_{ESS 1}^{′} \vert \\ arg ( Δ {\dot{I}}_{ESS 1}^{′} ) = arg ( Δ {\dot{I}}_{ESS 1} )\end{matrix}$$

where β is a transformation coefficient between the two reference coordinate systems, and is equal to a ratio of a rated current of the new energy converter to a rated current of the energy storage converter.

In Step S107, determine dq-axis currents of the energy storage converter according to the fault component of the current in the dq coordinate system of the energy storage converter and a rated current of the energy storage converter.

It should be noted that, in this embodiment, the rated current of the energy storage converter refers to an output current of the energy storage converter before the fault occurs, that is, an output current when the energy storage converter operates normally, which is referred to as the rated current in this embodiment.

In Step S108, control the energy storage converter to output current according to the dq-axis currents of the energy storage converter, so as to reduce an impact of the fault.

According to the technical solutions of the present disclosure, when a fault occurs, the energy storage converter is capable of outputting current based on calculated dq-axis currents, thereby reducing the impact of the fault. By estimating an output current of the new energy converter, the energy storage converter adjusts its own output current such that the overall output current of the new energy power plant satisfies requirements of conventional fault phase selection methods. Furthermore, after the fault lasts for a predetermined period of time, the control strategy is switched to a control strategy capable of achieving continuous and smooth active power regulation and stabilizing the voltage at the point of common coupling according to the voltage control objective, thereby ensuring improved performance of fault phase selection method for the new energy power plant.

In some embodiments, in response to a duration of the fault being greater than a predetermined time threshold, the energy storage converter outputs dq-axis currents according to a prescribed standard.

In this embodiment, the energy storage converter records a current time as tₙ, detects that a fault duration is tₗₐₛₜ=t_{f}−tₙ, and sets a control switching time of the energy storage converter as tₜᵣₐₙ. If tₗₐₛₜ>tₜᵣₐₙ, the energy storage converter needs to adjust positive- and negative-sequence dq-axis currents according to technical requirements for grid connection of onshore wind farms and photovoltaic power stations. Specifically, the following core conditions need to be satisfied: under an asymmetric fault scenario, dynamic reactive power support can be provided through adjustment of positive- and negative-sequence currents. For example, an onshore wind farm needs to inject positive-sequence dynamic reactive current to support recovery of positive-sequence voltage, and absorb negative-sequence dynamic reactive current to suppress rise of negative-sequence voltage. Meanwhile, low-voltage ride-through, high-voltage ride-through, and continuous ride-through capability are cooperatively realized, so as to ensure safe and stable grid-connected operation with the power system, and to satisfy related technical requirements such as power quality monitoring and secondary system security.

In some embodiments, in response to the duration of the fault being less than the predetermined time threshold, the method returns to Step S102, in which the energy storage converter determines an output current of the new energy converter after the fault occurs according to the pre-stored functional relationship between the voltage at the point of common coupling and the output current of the new energy converter and the voltage at the point of common coupling.

In this embodiment, the system can quickly return to a specified step to continue operation after a short-duration fault, thereby reducing the impact of the fault on an overall process, rapidly restoring a normal working state, and improving system stability and availability. Through continuous cyclic checking, transient faults that may repeatedly occur can be timely detected and processed, preventing fault accumulation or deterioration. This helps to discover potential hidden risks in the system in advance and perform targeted optimization and improvement. Such a closed-loop mechanism ensures that the system can still maintain normal functions and operating procedures when facing faults to a certain extent, enhances the capability of the system to cope with sudden situations, and improves overall reliability and robustness of the system.

In some embodiments, the step of “determining a fault component of a positive-sequence current of the energy storage converter in a dq coordinate system of the new energy converter according to the current fault component and the voltage fault component” comprises: determining a magnitude and an angle of the fault component of the positive-sequence current of the energy storage converter in the dq coordinate system;
the step of “determining a magnitude of the fault component of the positive-sequence current of the energy storage converter in the dq coordinate system” comprises:
determining an angle of the voltage fault component and an angle of the current fault component;
determining a difference between the angle of the voltage fault component and the angle of the current fault component;
determining a sine value according to the difference, a predetermined ideal angle, and a first constant, wherein the predetermined ideal angle is θ_{Plant1}. Optionally, θ_{Plant1} is 90 degrees, the first constant may be π; and
calculating a product of the current fault component and the sine value to obtain the magnitude of the fault component of the positive-sequence current of the energy storage converter in the dq coordinate system.

In some embodiments, the step of “determining a an angle of the fault component of the positive-sequence current of the energy storage converter in the dq coordinate system” comprises:
determining the angle of the fault component of the positive-sequence current of the energy storage converter in the dq coordinate system according to the angle of the voltage fault component, the predetermined ideal angle, and a second constant.

Wherein the second constant may be π/2.

In some embodiments, the step of “determining a fault component of a positive-sequence current of the energy storage converter in a dq coordinate system of the new energy converter according to the current fault component and the voltage fault component” comprises:
calculating the fault component of the positive-sequence current of the energy storage converter in the dq coordinate system according to the following equations:

$$\{ \begin{matrix}\vert Δ {\dot{I}}_{ESS 1} \vert = \vert Δ {\dot{I}}_{RES 1} \vert sin [ arg ( Δ {\dot{U}}_{PCC 1} ) - arg ( Δ {\dot{I}}_{RES 1} ) - {θ}_{Plant 1} + π ] \\ arg ( Δ {\dot{I}}_{ESS 1}^{′} ) = arg ( Δ {\dot{U}}_{PCC 1} ) - {θ}_{Plant 1} + π / 2\end{matrix} ;$$

where, Δİ_{RES1} is the current fault component, specifically a fault component of a positive-sequence current of the new energy converter in the dq coordinate system of the new energy converter;
Δİ_{ESS1}′ is the fault component of the positive-sequence current of the energy storage converter in the dq coordinate system;
Δ\dot{U}_{PCC1} is the voltage fault component, specifically a fault component of a positive-sequence voltage of the new energy converter in the dq coordinate system of the new energy converter;
θ_{Plant1} is the predetermined ideal angle

In some embodiments, the step of “determining dq-axis currents of the energy storage converter according to the fault component of the current in the dq coordinate system of the energy storage converter and a rated current of the energy storage converter” comprises:

$$\{ \begin{matrix}{i}_{d 1} = \vert Δ {\dot{I}}_{ESS 1 [ 0 ]} \vert sin {φ}_{pcc} + \vert Δ {\dot{I}}_{ESS 1} \vert sin [ arg ( Δ {\dot{I}}_{ESS 1} ) ] \\ {i}_{q 1} = \vert Δ {\dot{I}}_{ESS 1 [ 0 ]} \vert cos {φ}_{pcc} + \vert Δ {\dot{I}}_{ESS 1} \vert cos [ arg ( Δ {\dot{I}}_{ESS 1} ) ]\end{matrix} ;$$

where, Δİ_{ESS1[0]} is the rated current of the energy storage converter, specifically a pre-fault current of the energy storage converter;
φ_{pcc} is a voltage deviation angle before and after the fault, specifically a voltage deviation angle at the point of common coupling before and after the fault, that is, a voltage deviation angle of the energy storage converter before and after the fault;
i_{d1} is a d-axis current of the energy storage converter, specifically a positive-sequence d-axis current of the energy storage converter;
i_{q1} is a q-axis current of the energy storage converter, specifically a positive-sequence q-axis current of the energy storage converter; and
Δİ_{ESS1} is the fault component of the current of the energy storage converter in the dq coordinate system, specifically a current fault component of the energy storage converter before and after the fault in the dq coordinate system of the energy storage converter.

In this embodiment, considering that the new energy converter outputs a negative-sequence current under a fault condition, the energy storage converter does not need to output a negative-sequence current. That is, reference values of negative-sequence dq-axis currents of the energy storage converter are:

$$\{ \begin{matrix}{i}_{d 2} = 0 \\ {i}_{q 2} = 0\end{matrix}$$

In some embodiments, a transmission line model of a new energy power plant, as shown in FIG. 2, is established in PSCAD/EMTDC. The rated voltage of the transmission line is 220 kV, and the total length is 40 km, positive- and negative-sequence impedances are 0.076+j0.338∧/km, and the zero-sequence impedance is 0.284+j0.824∧/km. Positive-sequence and zero-sequence capacitances are 0.0086 uF/km, 0.0061 uF/km, respectively. Three-sequence impedances of an external system are all 2+j62.83∧. The new energy side is a 100 MW photovoltaic power station, and the corresponding energy storage capacity ratio is 20%. Points at 10%, 30%, 50%, and 90% of the transmission line are denoted as F1, F2, F3, and F4, respectively.

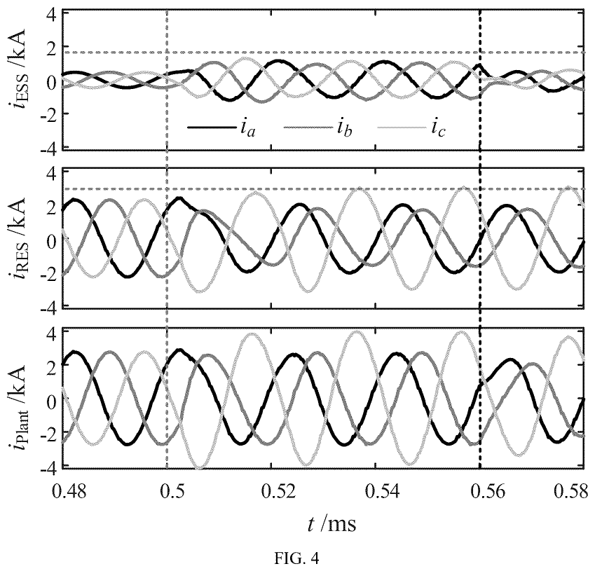

Referring to FIG. 4, an A-phase-to-ground fault is set at point F1. From top to bottom are current waveform diagrams of the energy storage converter, the new energy converter, and the new energy power plant. Waveform curves of different gray levels respectively correspond to an a-phase current iₐ, a b-phase current i_{b}, and a c-phase current i_{c}. Horizontal dashed lines indicate maximum current limiting amplitudes, gray vertical dashed lines correspond to fault occurrence moments, and black vertical dashed lines correspond to control strategy switching moments. Since a new energy control strategy switching time tₜᵣₐₙ=60 ms is configured, currents output by the energy storage converter and the new energy converter both increase after the fault occurs. The a-phase current output by the new energy converter reaches the maximum current limiting amplitude, while three-phase currents of the energy storage converter do not reach the maximum current limiting amplitude. After 60 ms, the amplitude of the current output by the energy storage converter decreases, because the control strategy is switched.

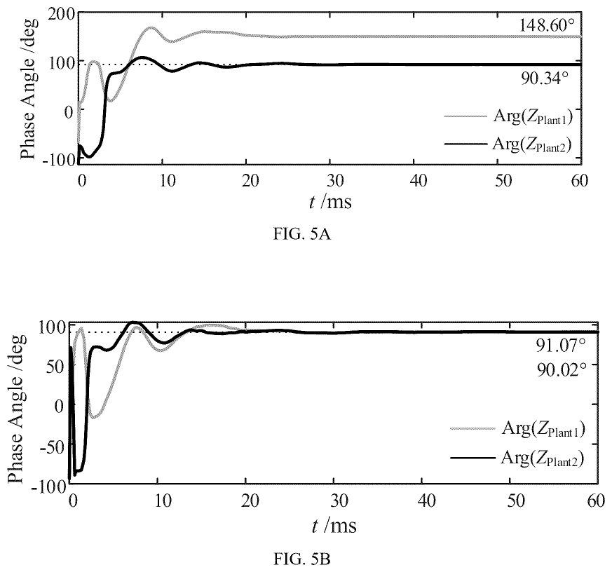

Referring to FIGS. 5A and 5B, positive- and negative-sequence equivalent impedances are plotted under the method of the present application and a conventional method. Z_{Plant1} represents a positive-sequence equivalent impedance of the new energy power plant, and Z_{Plant2} represents a negative-sequence equivalent impedance of the new energy power plant. After a time of one to two cycles after the fault occurs, the equivalent impedances Z_{Plant1} and Z_{Plant2} substantially reach a steady state. Referring to FIG. 5B, under the control strategy proposed in the present application, the positive- and negative-sequence equivalent impedances of the new energy power plant are 91.070 and 90.02°, respectively, which are substantially the same as the control target of 90°. However, under the conventional control method, the positive- and negative-sequence equivalent impedances of the new energy power plant are 148.600 and 90.34°, respectively, as shown in FIG. 5A, and the positive-sequence equivalent impedance under the conventional method significantly deviates from the control target of 90°.

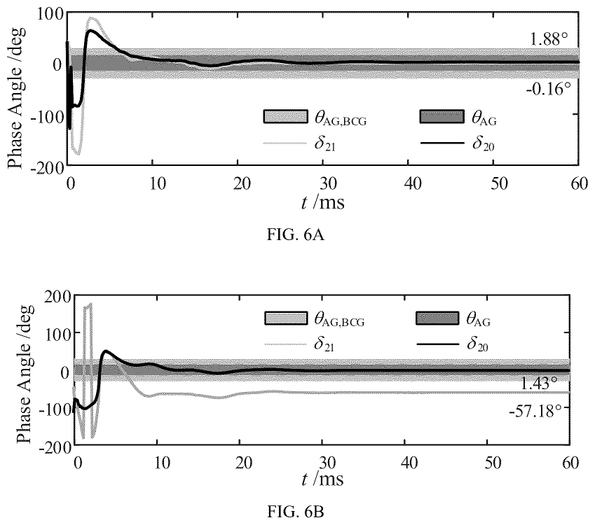

Referring to FIGS. 6A and 6B, impedance angles δ₂₁ and δ₂₀ corresponding to two control methods are respectively illustrated. Under the control strategy proposed in the present application, δ₂₁ and δ₂₀ are −0.16° and 1.88°, respectively. δ₂₁ is within a judgment region θ_{AG} of an A-phase-to-ground fault AG, and δ₂₀ is within a judgment region θ_{AG, BCG} of AG and BC two-phase-to-ground faults BCG. Therefore, a fault phase selection result under the control strategy proposed in the present application is AG. However, under the conventional control strategy, corresponding δ₂₁ and δ₂₀ are −57.18° and 1.43°, respectively. δ₂₁ is within a judgment region of a CA two-phase-to-ground fault CAG and is not within the judgment region θ_{AG, BCG} or θ_{AG}. δ₂₀ is within the judgment region θ_{AG, BCG} of AG and BCG. Since there is no overlapping judgment region for δ₂₁ and δ₂₀, a correct fault phase selection result cannot be obtained under the conventional control strategy.

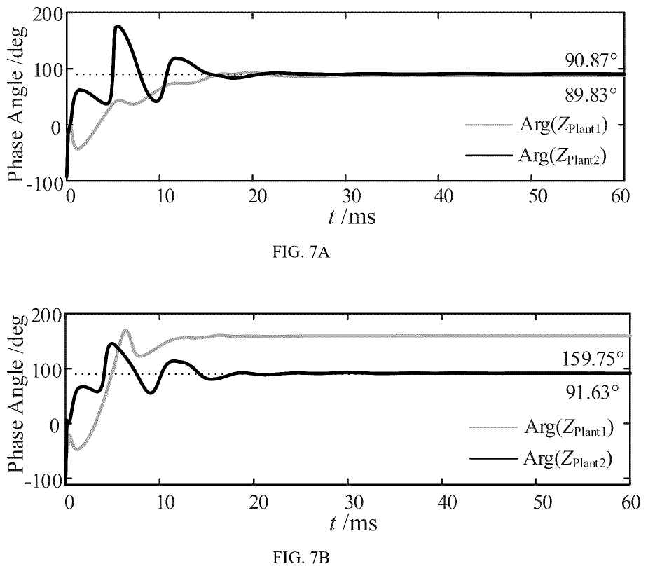

Referring to FIGS. 7A and 7B, when a fault type is changed to a BC two-phase-to-ground fault, curves of positive-sequence equivalent impedance Z_{Plant1} and negative-sequence equivalent impedance Z_{Plant2} of the new energy power plant under the proposed control strategy and the conventional control strategy are respectively obtained. As shown in FIG. 7A, under the control strategy proposed in the present application, the equivalent impedances Z_{Plant1} and Z_{Plant2} of the new energy power plant can still be maintained at approximately 90°. However, under the conventional control strategy, as shown in FIG. 7B, the equivalent impedances Z_{Plant1} and Z_{Plant2} of the new energy power plant are 159.750 and 91.63°, respectively, and the positive-sequence equivalent impedance Z_{Plant1} significantly deviates from 90°.

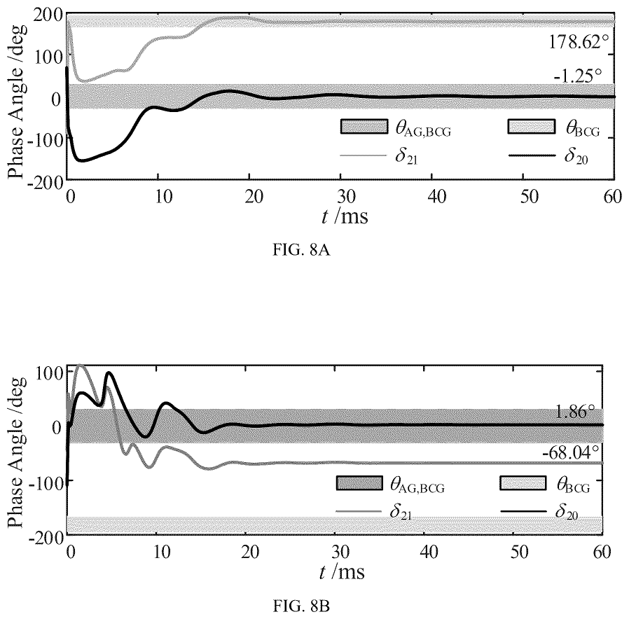

Referring to FIGS. 8A and 8B, impedance angles δ₂₁ and δ₂₀ corresponding to the control strategy proposed in the present application and the conventional control strategy are respectively illustrated. As shown in FIG. 8A, under the control strategy proposed in the present application, δ₂₁ and δ₂₀ are 178.620 and −1.25°, respectively. δ₂₁ is within the judgment region θ_{BCG} of BCG, and δ₂₀ is within the judgment region θ_{AG, BCG} of AG and BCG. Therefore, a fault phase selection result under the control strategy proposed in the present application is BCG. As shown in FIG. 8B, under the conventional control strategy, corresponding δ₂₁ and δ₂₀ are −68.04° and 1.43°, respectively. δ₂₁ is within the judgment region of CAG, and δ₂₀ is within the judgment region θ_{AG, BCG} of AG and BCG. Since the two do not have an overlapping judgment region, a correct fault phase selection result cannot be obtained under the conventional control strategy.

In summary, under a single-phase-to-ground fault or a two-phase-to-ground fault, the new energy power plant using the control strategy proposed in the present application can maintain positive- and negative-sequence equivalent impedance angles at a specific angle of 90°, thereby further ensuring restoration of fault phase selection capability of new energy side phase selection elements.

When the new energy power plant adopts the proposed control strategy, verification is performed by setting different fault points and different fault types, with a transition resistance set to 0Ω. Data within 50 ms after the fault occurs are recorded, and δ₂₁, δ₂₀, and fault phase selection results are calculated, as shown in Table 1. It can be seen from Table 1 that under different fault locations and different fault types, based on active control of the energy storage converter, the fault phase selection element can accurately determine a fault phase.

Referring to Table 1, influences of different fault locations and fault types on fault phase selection results are illustrated.

| Fault | Fault | | | Judgment |
|---|---|---|---|---|
| Location | Type | δ₂₁ | δ₂₀ | Result |
| F1 | AG | −0.16° | 1.88° | Correct |
| F1 | BCG | 178.62° | −1.25° | Correct |
| F2 | BG | 117.86° | −122.0°4 | Correct |
| F2 | CAG | −62.54° | −124.46° | Correct |
| F3 | CG | −118.51° | 117.89° | Correct |
| F3 | ABG | 57.79° | 116.98° | Correct |
| F4 | AG | 1.86° | −1.35° | Correct |
| F4 | BCG | 176.5°6 | −2.26° | Correct |

It can be understood that letters A, B, and C in Table 1 respectively correspond to three-phase lines of the power system, G denotes ground (grounding connection). Fault types AG, BG, and CG belong to single-phase-to-ground short-circuit faults, indicating that A-phase, B-phase, and C-phase lines of the power system are respectively short-circuited to ground G. Fault types BCG, CAG, and ABG belong to two-phase-to-ground short-circuit faults, indicating that BC two-phase, CA two-phase, and AB two-phase lines of the power system are respectively short-circuited to ground G. In combination with Table 1, it can be seen that at different fault points F1, F2, F3, or F4, regardless of whether a single-phase-to-ground short-circuit fault or a two-phase-to-ground short-circuit fault occurs, based on active control of the energy storage converter, the fault phase selection element can accurately determine the fault phase.

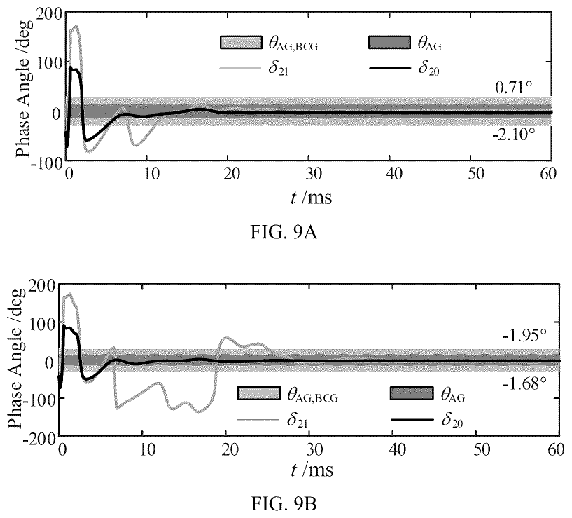

Referring to FIGS. 9A and 9B, when the new energy power plant adopts the proposed control strategy, an A-phase is set to be grounded at fault point F1 through transition resistances of 50Ω and 100Ω, respectively.

It can be seen from FIG. 9A that when the transition resistance is 50 Ω, δ₂₁ and δ₂₀ are 0.71° and −2.10°, respectively, and both δ₂₁ and δ₂₀ are within the judgment region θ_{AG} of AG.

It can be seen from FIG. 9B that when the transition resistance is 100 Ω, δ₂₁ and δ₂₀ are −1.95° and −1.68°, respectively, and both δ₂₁ and δ₂₀ are within the judgment region θ_{AG} of AG.

That is, when the transition resistance is 50Ω or 100 Ω, δ₂₁ and δ₂₀ are both within the judgment region θ_{AG} of AG, and the fault phase can be correctly determined. Therefore, the proposed control strategy can enable the fault phase selection element to have good performance even under a relatively high transition resistance condition.

Finally, it should be noted that the above content is only used to illustrate the technical solutions of the present disclosure, and is not intended to limit the scope of protection of the present disclosure. Simple modifications or equivalent substitutions made by those of ordinary skill in the art to the technical solutions of the present disclosure shall not depart from the spirit and scope of the technical solutions of the present disclosure.

What is claimed is:

1. A control method for an energy storage converter, comprising:
determining a voltage at a point of common coupling of the energy storage converter and a new energy converter;
determining, based on a pre-stored functional relationship between the voltage at the point of common coupling and an output current of the new energy converter, and the voltage at the point of common coupling, an output current of the new energy converter after a fault occurs;
determining a current fault component according to the output current of the new energy converter and a rated operating current of the new energy converter;
determining a voltage fault component according to the voltage at the point of common coupling and a rated operating voltage of the new energy converter;
determining a fault component of a positive-sequence current of the energy storage converter in a dq coordinate system of the new energy converter according to the current fault component and the voltage fault component, comprising: determining a magnitude and an angle of the fault component of the positive-sequence current of the energy storage converter in the dq coordinate system;
wherein the step of “determining a magnitude of the fault component of the positive-sequence current of the energy storage converter in the dq coordinate system” comprises:
determining an angle of the voltage fault component and an angle of the current fault component;
determining a difference between the angle of the voltage fault component and the angle of the current fault component;
determining a sine value according to the difference, a predetermined ideal angle, and a first constant; and
calculating a product of the current fault component and the sine value to obtain the magnitude of the fault component of the positive-sequence current of the energy storage converter in the dq coordinate system;
determining a fault component of a current in a dq coordinate system of the energy storage converter according to the fault component of the current in the dq coordinate system of the new energy converter and a transformation coefficient;
determining dq-axis currents of the energy storage converter according to the fault component of the current in the dq coordinate system of the energy storage converter and a rated current of the energy storage converter; and
controlling the energy storage converter to output current according to the dq-axis currents of the energy storage converter, so as to reduce an impact of the fault.

2. The control method according to claim 1, wherein, in response to a duration of the fault being greater than a predetermined time threshold, the energy storage converter outputs dq-axis currents according to a prescribed standard.

3. The control method according to claim 1, wherein, in response to a duration of the fault being less than a predetermined time threshold, the method returns to the step of “determining, based on a pre-stored functional relationship between the voltage at the point of common coupling and an output current of the new energy converter, and the voltage at the point of common coupling, an output current of the new energy converter after a fault occurs”.

4. The control method according to claim 1, wherein, the step of “determining a an angle of the fault component of the positive-sequence current of the energy storage converter in the dq coordinate system” comprises:
determining the angle of the fault component of the positive-sequence current of the energy storage converter in the dq coordinate system according to the angle of the voltage fault component, the predetermined ideal angle, and a second constant.

5. The control method according to claim 4, wherein, the step of “determining a fault component of a positive-sequence current of the energy storage converter in a dq coordinate system of the new energy converter according to the current fault component and the voltage fault component” comprises:
calculating the fault component of the positive-sequence current of the energy storage converter in the dq coordinate system according to the following equations:
$$\{ \begin{matrix}\vert Δ {\dot{I}}_{ESS 1}^{′} \vert = \vert Δ {\dot{I}}_{RES 1} \vert sin [ arg ( Δ {\dot{U}}_{PCC 1} ) - arg ( Δ {\dot{I}}_{RES 1} ) - {θ}_{Plant 1} + π ] \\ arg ( Δ {\dot{I}}_{ESS 1}^{′} ) = arg ( Δ {\dot{U}}_{PCC 1} ) - {θ}_{Plant 1} + π / 2\end{matrix} ;$$
where, Δİ_{RES1} is the current fault component;
Δİ_{ESS1}′ is the fault component of the positive-sequence current of the energy storage converter in the dq coordinate system;
Δ\dot{U}_{PCC1} is the voltage fault component;
θ_{Plant1} is the predetermined ideal angle.

6. The control method according to claim 1, wherein, the step of “determining dq-axis currents of the energy storage converter according to the fault component of the current in the dq coordinate system of the energy storage converter and a rated current of the energy storage converter” comprises:
$$\{ \begin{matrix}{i}_{d 1} = \vert Δ {\dot{I}}_{ESS 1 [ 0 ]} \vert sin {φ}_{pcc} + \vert Δ {\dot{I}}_{ESS 1} \vert sin [ arg ( Δ {\dot{I}}_{ESS 1} ) ] \\ {i}_{q 1} = \vert Δ {\dot{I}}_{ESS 1 [ 0 ]} \vert cos {φ}_{pcc} + \vert Δ {\dot{I}}_{ESS 1} \vert cos [ arg ( Δ {\dot{I}}_{ESS 1} ) ]\end{matrix} ;$$
where, Δİ_{ESS1[0]} is the rated current of the energy storage converter;
φ_{pcc} is a voltage deviation angle before and after the fault;
i_{d1} is a d-axis current of the energy storage converter;
i_{q1} is a q-axis current of the energy storage converter; and
Δİ_{ESS1} is the fault component of the current of the energy storage converter in the dq coordinate system.

7. The control method according to claim 1, wherein, the voltage at the point of common coupling of the energy storage converter is identical to the voltage at the point of common coupling of the new energy converter.

8. The control method according to claim 7, wherein, the functional relationship between the voltage at the point of common coupling and the output current of the new energy converter is expressed as:
$$\{ \begin{matrix}{\dot{I}}_{RES 1} = {f}_{RES 1} ( {\dot{U}}_{PCC 1} ) \\ {\dot{I}}_{RES 2} = {f}_{RES 2} ( {\dot{U}}_{PCC 2} )\end{matrix} ;$$
where, İ_{RES1} is the positive-sequence current output by the new energy converter;
İ_{RES2} is a negative-sequence current output by the new energy converter;
\dot{U}_{PCC1} is a positive-sequence voltage at the point of common coupling;
\dot{U}_{PCC2} is a negative-sequence voltage at the point of common coupling;
f_{RES1} is a first function; and
f_{RES2} is a second function.

9. The control method according to claim 1, wherein, before determining the voltage at the point of common coupling of the energy storage converter and the new energy converter, the method further comprises: determining that a fault occurs; and
after determining the voltage at the point of common coupling of the energy storage converter and the new energy converter, the method further comprises: controlling the energy storage converter, in response to the voltage at the point of common coupling dropping to a predetermined threshold, to enter a low-voltage ride-through stage.
